(19) United States
(12) Patent Application Publication
(10) Pub. No.: US 2012/0019113 A1
(43) Pub. Date: Jan. 26, 2012

(54) Device Case and Mounting Apparatus With Flexible Support Legs

(76) Inventor: Eric C. Hale, San Francisco, CA (US)

(21) Appl. No.: 13/187,541

(22) Filed: Jul. 21, 2011

Related U.S. Application Data
(60) Provisional application No. 61/367,454, filed on Jul. 26, 2010.
(60) Provisional application No. 61/407,410, filed on Oct. 27, 2010.

(51) Int. Cl. H05K 5/02

(52) U.S. Cl. 312/223.1

(57) ABSTRACT

A support case with flexible support legs for an electronic device, such as a tablet computer. The case may be adapted to support the tablet in a variety of configuration with the use of the flexible supports. The case may also protect the electronic device from rough contact and other wear. The support legs may also be used as gripping arms and wrapped around items.

### CROSS-REFERENCE TO RELATED APPLICATIONS

This application claims priority to U.S. Provisional Patent Application No. 61/367,454 to Hale, filed Jul. 26, 2010, which is hereby incorporated by reference. This application claims priority to U.S. Provisional Patent Application No. 61/407,410 to Hale, filed Oct. 27, 2010, which is hereby incorporated by reference.

### BACKGROUND

1. Field of the Invention

The present invention relates to a device case and mounting apparatus with flexible supports, adapted to support an item mounted in the device case in a variety of configurations.

2. Description of Related Art

Modern portable electronic devices, such as tablet computing devices, are not well adapted to be positioned other than on a flat surface, with the screen facing directly vertically. These items are typically flat, rectangular objects which may be difficult to place in an appropriate position for hands-free use while viewing. They may also be of a somewhat environmentally and impact sensitive nature.

Such devices may be enhanced with the use of a case which affords protection for the device. The use of a tablet device may be enhanced with the use of a support structure. What is called for is a case that may also function as a mounting apparatus. What is also called for is a case for a tablet device which allows the support or mounting of the tablet device in multiple positions.

### SUMMARY

A support case with flexible support legs for an electronic device, such as a tablet computer. The case may be adapted to support the tablet in a variety of configuration with the use of the flexible supports. The case may also protect the electronic device from rough contact and other wear. The support legs may also be used as gripping arms and wrapped around items.

### BRIEF DESCRIPTION OF THE DRAWINGS

FIG. 1 illustrates a top view of a device case and mounting apparatus in a stowed configuration according to some embodiments of the present invention.

FIG. 2 illustrates a bottom view of a device case and mounting apparatus in a stowed configuration according to some embodiments of the present invention.

FIG. 3 illustrates a top edge view of a device case and mounting apparatus in a stowed configuration according to some embodiments of the present invention.

FIG. 4 illustrates a side edge view of a device case and mounting apparatus in a stowed configuration according to some embodiments of the present invention.

FIG. 5 illustrates a device case and mounting apparatus in a first deployed configuration according to some embodiments of the present invention.

FIG. 6 illustrates a device case and mounting apparatus in a first deployed configuration according to some embodiments of the present invention.

FIG. 7 illustrates a device case and mounting apparatus in a second deployed configuration according to some embodiments of the present invention.

FIG. 8 illustrates a device case and mounting apparatus in a second deployed configuration according to some embodiments of the present invention.

FIG. 9 illustrates a device case and mounting apparatus with its legs attached as to support a landscape view according to some embodiments of the present invention.

FIG. 10 illustrates a device case and mounting apparatus with its legs attached as to support a landscape view according to some embodiments of the present invention.

FIG. 11 illustrates a device case and mounting apparatus with its legs attached as to support a landscape view according to some embodiments of the present invention.

FIG. 12 illustrates a device case and mounting apparatus with its legs attached as to support a landscape view according to some embodiments of the present invention.

FIG. 13 illustrates a device case and mounting apparatus with its legs attached as to support a portrait view according to some embodiments of the present invention.

FIG. 14 illustrates a device case and mounting apparatus with its legs attached as to support a portrait view according to some embodiments of the present invention.

FIG. 15 illustrates a device case and mounting apparatus with its legs attached as to support a portrait view according to some embodiments of the present invention.

FIG. 16 illustrates a device case and mounting apparatus with its legs attached as to support a portrait view according to some embodiments of the present invention.

FIG. 17 illustrates an exploded view of a device case and a leg set according to some embodiments of the present invention.

FIG. 18 illustrates an exploded view of an electronic device, a device case, and a leg set according to some embodiments of the present invention.

FIG. 19 illustrates the device case and leg set interface according to some embodiments of the present invention.

FIG. 20 illustrates the device case and leg set interface according to some embodiments of the present invention.

FIG. 21 illustrates the device case and leg set interface according to some embodiments of the present invention.

### DETAILED DESCRIPTION

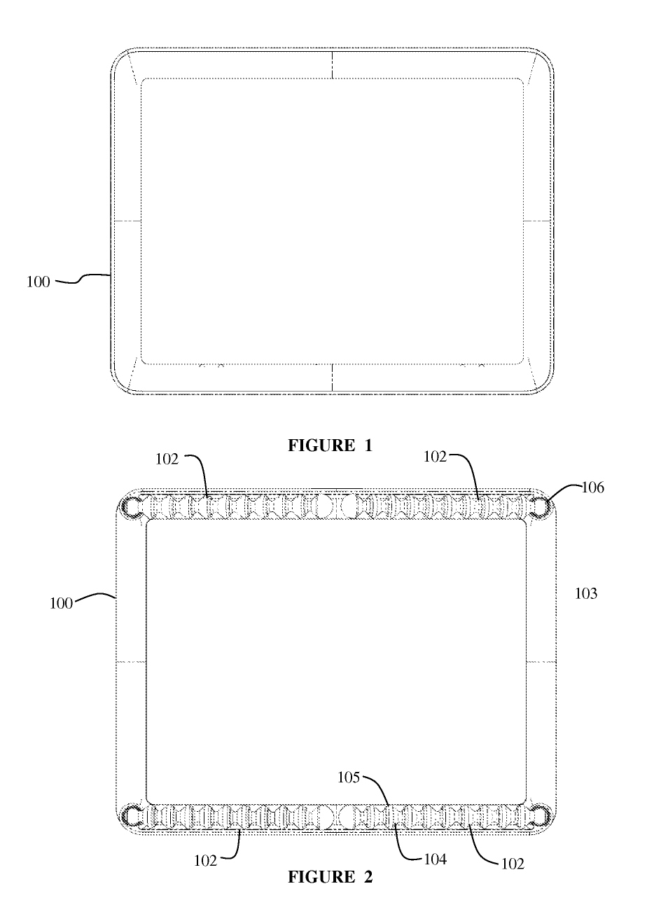

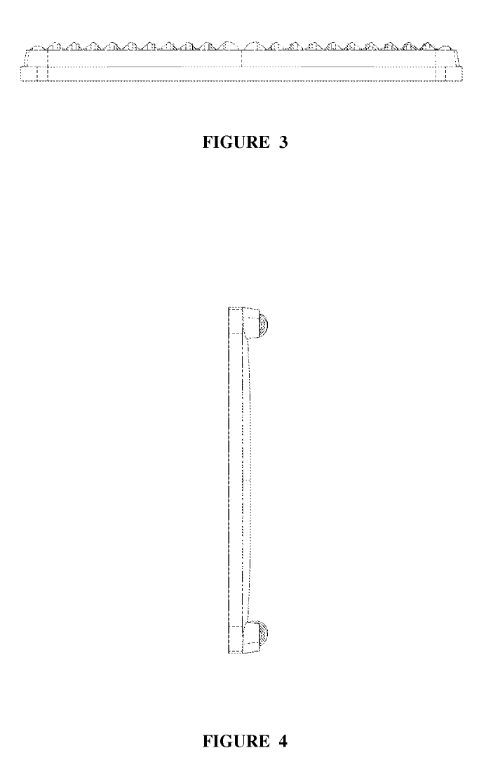

FIGS. 1-4 illustrate the stowed configuration of device case and mounting apparatus 100 adapted to retain an electronic device according to some embodiments of the present invention. In some embodiments, the electronic device is a tablet computing device. The electronic device may also be another device. The electronic device may have a screen.

In some embodiments, the device case and mounting apparatus 100 is adapted to be a protective case as well as a support for viewing the electronic device, which may be a tablet, in a variety of positions. When in the stowed configuration, the device case and mounting apparatus may still allow access to device ports along the side of the device, which may be used to charge the device, or for other reasons.

As seen in FIG. 2, a plurality of flexible legs 102 are seen stowed along the rear of the device receiver portion 103. The device receiver portion 103 may be adapted to fit around an electronic device and to hold it in the assembly. The flexible legs 102 may be ball and socket connectors 104 interconnected into a leg assembly. The connectors may include a gripping portion 105 on the outer surface of the socket end of the connector which adapted to provide a gripping frictional surface when the flexible legs are used as gripping arms, such as when wrapped around a slender object. The flexible legs 102 may be attached to the device receiver portion 103 with a ball and socket 106 to afford full flexibility and to be adapted to a lower profile stowed position.

In the stowed configuration, the flexible legs 102 may lie flat along the back of the apparatus. With the gripping portions 105 as the outermost portion of the legs, the frictional gripping portions may provide a non-slip type surface along the back of the device which enhances the grip of the device when in use in this stowed configuration. For example, the electronic device, such as a tablet computer, may be in the apparatus and laid down on a table, but with much better grip than if not in the mounting apparatus.

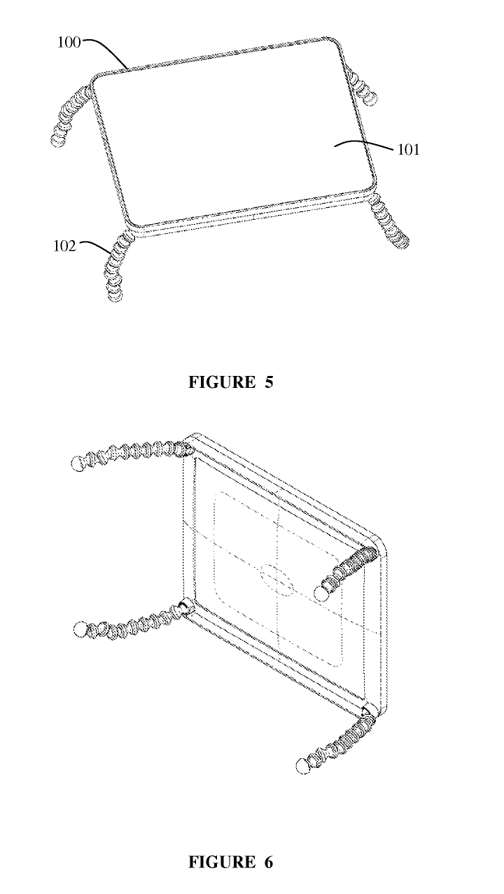

FIGS. 5 and 6 illustrate the device case and mounting apparatus 100 in a first deployed configuration, as it may be when used on a table top, for example. The flexible legs 102 may be swiveled out an angle, which may be a right angle, which facilitates their use as legs on a surface. In some aspects, the legs may be used to place the device in a horizontal position. In other aspects, other positions, including angled positions, may be selected by the user. The flexible nature of the legs 102, which may be ball and socket connectors 104 interconnected to form a flexible leg, allows for a multiplicity of positions.

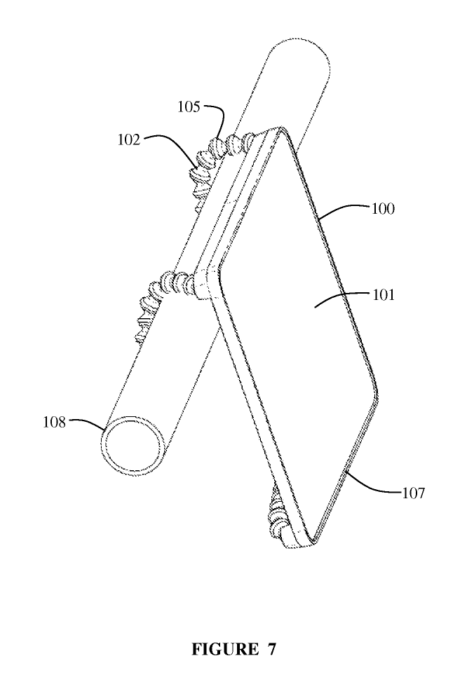

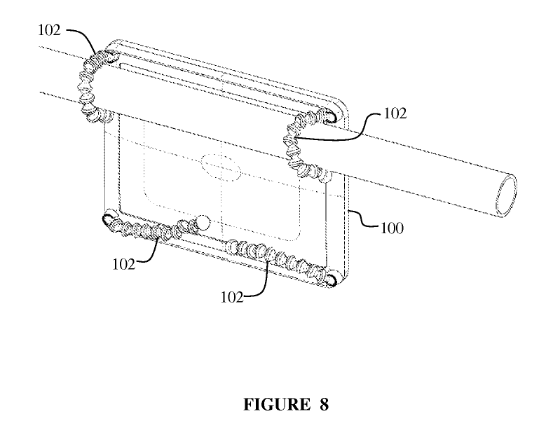

FIGS. 7 and 8 illustrate the device case and mounting apparatus 100 in a second deployed configuration. The tablet 100 with its screen is mounted within the device receiver portion 103. A rim 107, or series of rim portions, of the device receiver 103 may have a lip which helps hold the tablet in place. The flexible legs 102 are seen wrapped around an item such as a tubular cross member 108. The gripping portion 105 of the legs may help with the grip of the legs 102 on the cross member 108.

In some embodiments of the present invention, a device support 200 is used with a device receiver 210 and a removable and movable leg set 201. The device support may allow for the leg set to be attached in a variety of configurations.

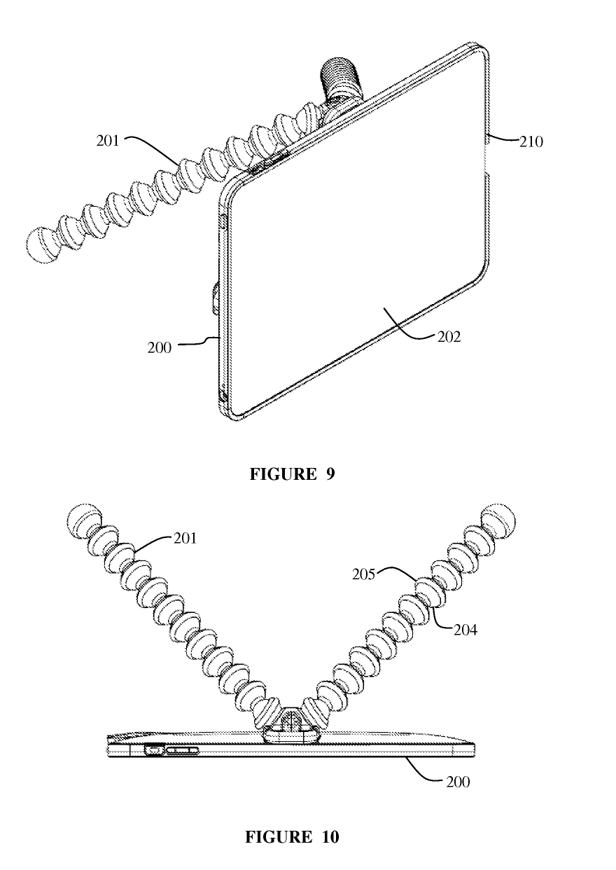

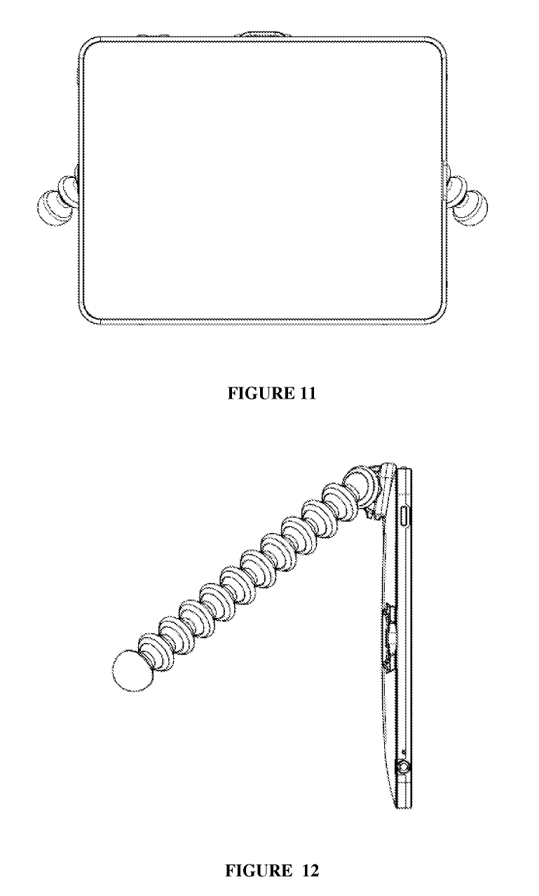

As seen in FIGS. 9-12, a removable leg 201 set may be attached to a device support 200 in a configuration adapted to allow the use on an electronic device 202, such as a tablet, in a landscape mode. Although any number of viewing modes are available with the leg set so attached, a landscape mode view is well suited in the configuration seen in FIGS. 9-12. As seen in FIG. 9, the leg set 201 is attached to the device support along the long side, and near the edge of the back of the device support. This allows the device to be supported as if in a picture frame when the legs are kept straight, and separated somewhat. The legs may be flexible, and may be adapted to wrap around object in order to support the device support and an electronic device mounted therein.

The leg set 201 may be ball and socket connectors 204 interconnected into a leg assembly. The connectors 204 may include a gripping portion 205 on the outer surface of the socket end of the connector which adapted to provide a gripping frictional surface when the legs are used as gripping arms, such as when wrapped around a slender object.

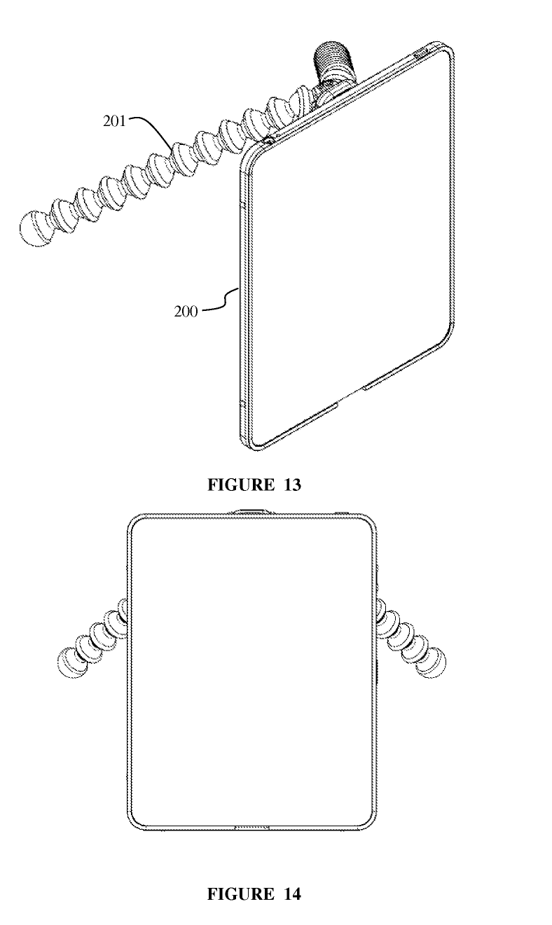

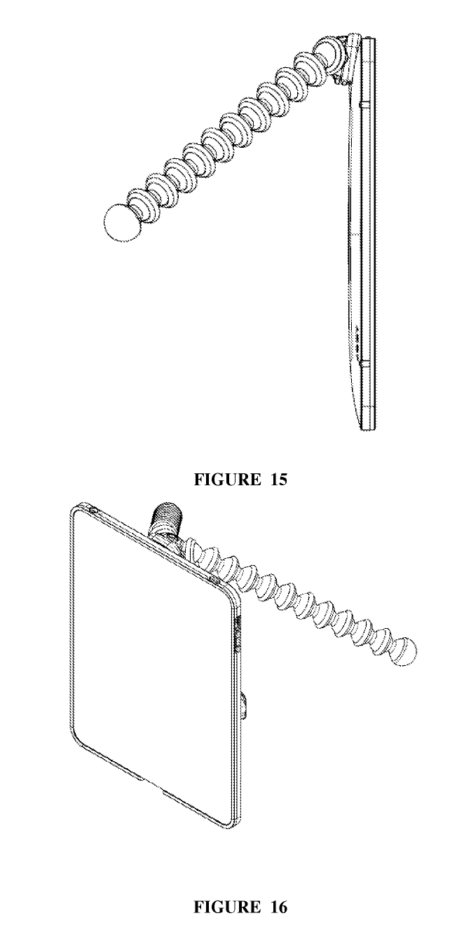

FIGS. 13-16 illustrate a configuration wherein the leg set 201 has been attached to a second attach point on the back of the device support. This configuration is better adapted to allow for viewing in portrait mode. A device support with a leg set that is removable and adapted to be attached in a variety of locations as discussed herein provides a great range of options to a user.

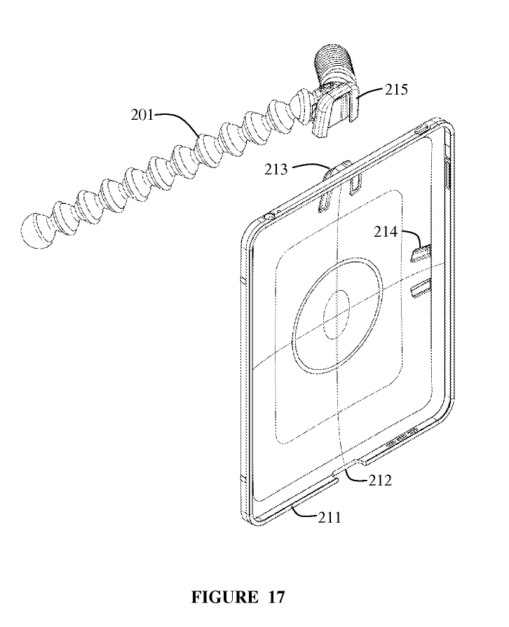

FIG. 17 illustrates a leg set and the device support. As seen, the leg set 201 has a clip receiver 215 and the device receiver has a first integral clip 213 and a second integral clip 215. The 90 degree offsets of the first integral clip 213 and the second integral clip 215 allow for different orientations of the tablet while supported by the leg set 201. The device receiver 210 is adapted to receive and support a device such as a tablet computer. A rim 211 may be used to firmly constrain the tablet within the device receiver 210. Cutouts 212 may be used to allow access to portions of the tablet which would otherwise be blocked by the rim 211.

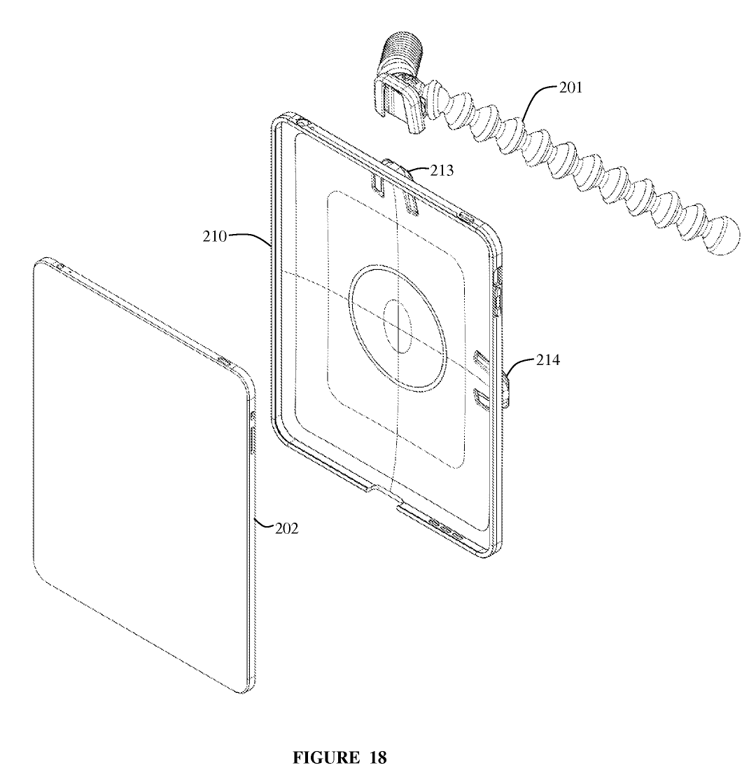

FIG. 18 illustrates a tablet device 202, a device receiver 210, and a leg set 201 in exploded view.

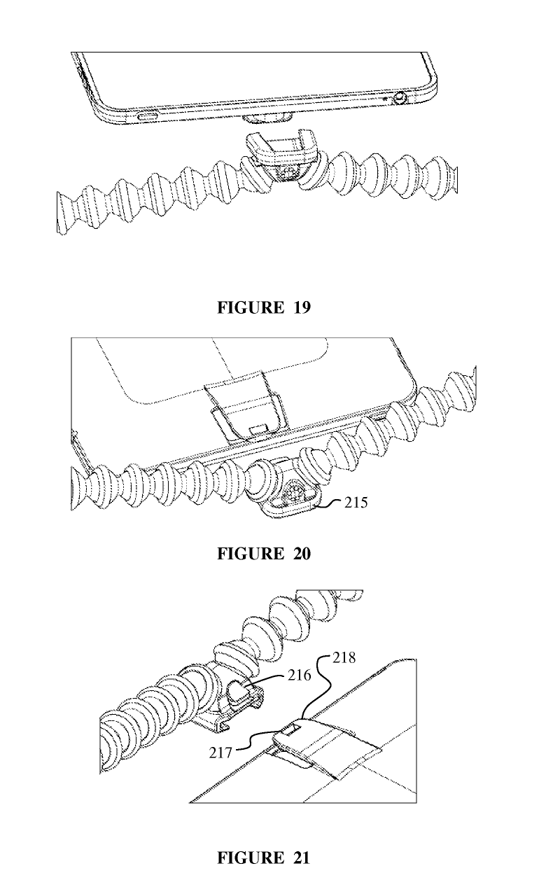

FIGS. 19-21 are more detailed views of the interface area of the clip receiver 215 and the leg set 201. The clips may have a raised platform 218 with a flange running around the perimeter adapted to reside within the clip receiver 215. A slot 217 in the clip may provide a recess for a spring loaded snap to snap into the clip as the clip is inserted into the clip receiver 215. A release tab 216 may withdraw the spring loaded snap from the slot 217 for removal of the leg set 201 from the device receiver, although the leg set may be firmly held to the device receiver when snapped into place.

As evident from the above description, a wide variety of embodiments may be configured from the description given herein and additional advantages and modifications will readily occur to those skilled in the art. The invention in its broader aspects is, therefore, not limited to the specific details and illustrative examples shown and described. Accordingly, departures from such details may be made without departing from the spirit or scope of the applicant's general invention.

I claim:

1. A case and support assembly for an electronic device, said case and support assembly comprising:
a device receiver portion, said device receiver portion adapted to support and hold an electronic device; and
a plurality of flexible legs, said flexible legs attached to said device receiver portion.

2. The case and support assembly of claim 1 wherein each of said flexible legs is composed of a multiplicity of connector pieces that join together in ball and socket joints that permit pivotable movement between connecting ball and socket components.

3. The case and support assembly of claim 2 wherein said legs have sufficient flexibility to substantially wrap around an object.

4. The case and support assembly of claim 2 wherein each ball and socket joint comprises a gripping member formed on an exterior surface of the associated socket member portion, the gripping member being formed from a different material than the associated socket member portion and having a maximum diameter that is greater than a maximum diameter of the associated socket member portion.

5. The case and support assembly of claim 3 wherein each ball and socket joint comprises a gripping member formed on an exterior surface of the associated socket member portion, the gripping member being formed from a different material than the associated socket member portion and having a maximum diameter that is greater than a maximum diameter of the associated socket member portion.

6. The case and support assembly of claim 1 wherein said device receiver is rectangular, and wherein a flexible leg is attached to each corner of said rectangular device receiver.

7. The case and support assembly of claim 5 wherein said device receiver is rectangular, and wherein a flexible leg is attached to each corner of said rectangular device receiver.

8. The case and support assembly of claim 7 wherein said device receiver comprises a rim around its periphery adapted to retain an electronic device.

9. A case and support assembly for an electronic device, said case and support assembly comprising:
a device receiver portion, said device receiver portion adapted to support and hold an electronic device; and
a set of flexible legs attached to said device receiver portion.

10. The case and support assembly of claim 9 wherein said set of flexible legs comprises two legs attached to a clip receiver body.

11. The case and support assembly of claim 10 wherein said device receiver comprises a plurality of clips, said clips adapted to mate with said clip receiver body.

12. The case and support assembly of claim 11 wherein said device receiver is rectangular.

13. The case and support assembly wherein said device receiver comprises a first clip along a first edge and a second clip along a second edge, wherein said first edge and said second edge are directly adjacent.

14. The case and support assembly of claim 13 wherein said flexible legs are composed of a multiplicity of connector pieces that join together in ball and socket joints that permit pivotable movement between connecting ball and socket components.

15. The case and support assembly of claim 14 wherein each ball and socket joint comprises a gripping member formed on an exterior surface of the associated socket member portion, the gripping member being formed from a different material than the associated socket member portion and having a maximum diameter that is greater than a maximum diameter of the associated socket member portion.
